(19) United States
(12) Patent Application Publication
(10) Pub. No.: US 2009/0189201 A1
(43) Pub. Date: Jul. 30, 2009

(54) INWARD DIELECTRIC SPACERS FOR REPLACEMENT GATE INTEGRATION SCHEME

(76) Inventors: Chorng-Ping Chang, Saratoga, CA (US); Bingxi Sun Wood, Cupertino, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/019,538

(22) Filed: Jan. 24, 2008

(51) Int. Cl. H01L 21/44; H01L 29/78

(52) U.S. Cl. 257/288; 438/595; 257/E21.476; 257/E29.255

(57) ABSTRACT

Inward dielectric spacers for a replacement gate integration scheme are described. A semiconductor device is fabricated by first providing a substrate having thereon a placeholder gate electrode disposed in a dielectric layer. The placeholder gate electrode is removed to from a trench in the dielectric layer. A pair of dielectric spacers is then formed adjacent to the sidewalls of the trench. Finally, a gate electrode is formed in the trench and adjacent to the pair of dielectric layers.

### BACKGROUND OF THE INVENTION

1) Field of the Invention

The invention is in the fields of Semiconductor Devices and Semiconductor Processing.

2) Description of Related Art

For the past several decades, the scaling of features in integrated circuits has been the driving force behind an ever-growing semiconductor industry. Scaling to smaller and smaller features enables increased densities of functional units on the limited real estate of semiconductor chips. For example, shrinking transistor size allows for the incorporation of an increased number of logic and memory devices on a microprocessor, lending to the fabrication of products with increased complexity. Scaling has not been without consequence, however. As the dimensions of the fundamental building blocks of microelectronic circuitry are reduced and as the sheer number of fundamental building blocks fabricated in a given region is increased, the performance requirements of the materials used in these building blocks have become exceedingly demanding. One example is the change from poly-crystalline silicon to metal gate electrodes in complimentary metal-oxide-semiconductor (CMOS) transistors, starting at around the 45 nm technology node.

Metal gate electrodes for CMOS transistors can be fabricated in a replacement gate integration scheme. However, as constraints on dimensions increase, problems may arise with conventional approaches. For example, FIG. 1A illustrates a cross-sectional view representing a step in a conventional replacement gate integration scheme, in accordance with the prior art.

Referring to FIG. 1A, a partially completed semiconductor device 100 is formed in and above a substrate 102. Source and drain regions 104 define a channel region 106 in substrate 102 and underneath a gate dielectric layer 108. A trench 110 is formed in a dielectric layer 112 and, in particular, in between a pair of outward dielectric spacers 114. In a replacement gate integration scheme, the gate electrode is formed by depositing a metal layer 116 over partially completed semiconductor device 100 to fill at least a portion of trench 110. However, the bottom of trench 110 may not be uniformly filled if the width of trench 110 is too small in relation to the deposition technique used to deposit metal layer 116, as depicted in FIG. 1A. Thus, seams 118 may undesirably be formed where metal layer 116 meets the sidewalls and the bottom of trench 110.

The issues described in association with FIG. 1A may be exacerbated when the sidewalls of a replacement gate trench have a re-entrant profile. For example, FIG. 1B illustrates a cross-sectional view representing a step in a conventional replacement gate integration scheme, in accordance with the prior art.

Referring to FIG. 1B, a partially completed semiconductor device 120 is formed in and above a substrate 122. The sidewalls of a trench 130 have a re-entrant profile, in that they slope inwards in moving from the bottom of trench 130 to the top of trench 130. In this case, the bottom of trench 130 and, consequently, the top of a gate dielectric layer 128, may receive even less uniform coverage by a deposited metal layer 136. Thus, seams 138 formed where metal layer 136 meets the sidewalls and the bottom of trench 130 may be even more troublesome.

Thus, inward dielectric spacers for a replacement gate integration scheme are described herein.

### BRIEF DESCRIPTION OF THE DRAWINGS

FIG. 1A illustrates a cross-sectional view representing a step in a conventional replacement gate integration scheme, in accordance with the prior art.

FIG. 1B illustrates a cross-sectional view representing a step in a conventional replacement gate integration scheme, in accordance with the prior art.

FIG. 2 illustrates a cross-sectional view representing a semiconductor device having inward dielectric spacers, in accordance with an embodiment of the present invention.

FIG. 3 illustrates a cross-sectional view representing a semiconductor device having inward dielectric spacers adjacent to the sidewalls of a trench having a re-entrant profile, in accordance with an embodiment of the present invention.

FIG. 4 illustrates a cross-sectional view representing a semiconductor device having inward dielectric spacers and a replacement gate dielectric layer, in accordance with an embodiment of the present invention.

FIGS. 5A-5H illustrate cross-sectional views representing operations in a replacement gate integration scheme incorporating inward dielectric spacers, in accordance with an embodiment of the present invention.

FIG. 6 illustrates a cross-sectional view representing an operation in a replacement gate integration scheme incorporating inward dielectric spacers and a replacement gate dielectric layer, in accordance with an embodiment of the present invention.

FIGS. 7A-7D illustrate cross-sectional views representing an operation in a replacement gate integration scheme incorporating inward dielectric spacers adjacent to the sidewalls of a trench having re-entrant profile, in accordance with an embodiment of the present invention.

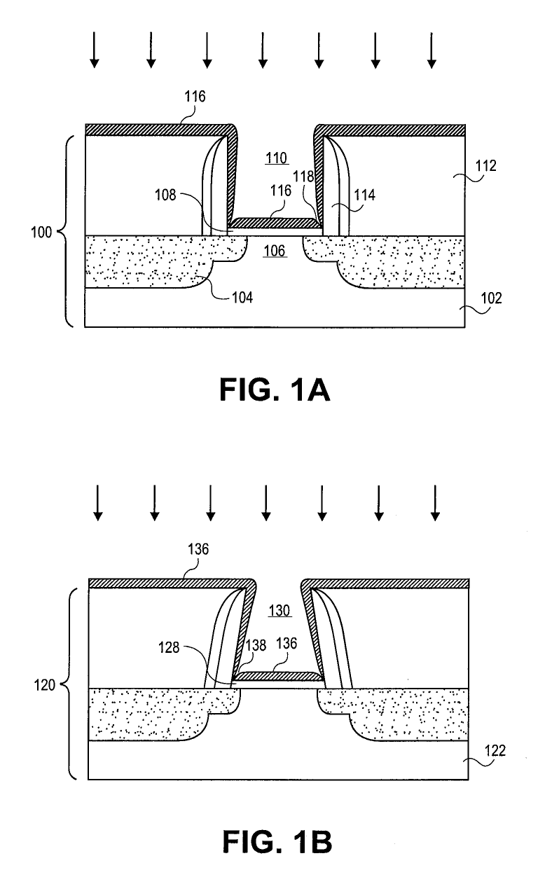

### DETAILED DESCRIPTION

Inward dielectric spacers for a replacement gate integration scheme are described. In the following description, numerous specific details are set forth, such as fabrication conditions and material regimes, in order to provide a thorough understanding of the present invention. It will be apparent to one skilled in the art that the present invention may be practiced without these specific details. In other instances, well-known features, such as integrated circuit design layouts, are not described in detail in order to not unnecessarily obscure the present invention. Furthermore, it is to be understood that the various embodiments shown in the Figures are illustrative representations and are not necessarily drawn to scale.

Disclosed herein are inward dielectric spacers for a replacement gate integration scheme. A semiconductor device may be fabricated by first providing a substrate having thereon a placeholder gate electrode disposed in a dielectric layer. In an embodiment, the placeholder gate electrode is removed to form a trench in the dielectric layer. A pair of inward dielectric spacers may then be formed adjacent to the sidewalls of the trench. In one embodiment, a gate electrode is formed in the trench and adjacent to the pair of inward dielectric spacers. In a specific embodiment, the top portion of each inward dielectric spacer is flared to form a funnel shape. In a particular embodiment, the trench in the dielectric layer has a re-entrant profile and each inward dielectric spacer has a tapered profile. In another embodiment, the inward dielectric spacers include a material having a dielectric constant approximately in the range of 2.2-3.5, i.e. a “low-K” material.

The use of inward dielectric spacers for a replacement gate integration scheme may enable the compatibility of ever-smaller trench widths with various material deposition techniques. For example, in accordance with an embodiment of the present invention, the tapered profile for an inward dielectric spacer directs deposited material to the bottom of a trench being filled to form a gate electrode. This may allow for total and uniform coverage of the bottom of the trench by a deposited material, effectively eliminating the formation of gaps at the corners of the filled trench. The trench filling process may be further enhanced when the top portion of each inward dielectric spacer is flared. Thus, in one embodiment, the top portion of each inward dielectric spacer is flared to form a funnel shape. The funnel shape may aid with further directing deposited material to the bottom of a trench being filled with the gate electrode material. In the case of a trench having a re-entrant profile, inward dielectric spacers may correct for such a profile by rendering a tapered profile for the trench.

The use of inward dielectric spacers for a replacement gate integration scheme may also ease the constraints of the lithography process used at the gate patterning step. In accordance with an embodiment of the present invention, inward dielectric spacers are used to shrink the width of a trench used to form a gate electrode. Thus, the critical dimension of a placeholder gate electrode need not be as small as the dimension of the desired final gate electrode because the inward dielectric spacers may reduce the width of the trench created upon removing the placeholder gate electrode. In one embodiment, this reduction in trench width is carried out subsequent to the lithography process used to form the placeholder gate electrode and can therefore shrink the critical dimension normally achievable by a particular lithographic process. In a similar manner, the use of inward dielectric spacers for a replacement gate integration scheme may enable a more efficient process flow. For example, prevailing sub-100 nm technologies typically use two sets of spacers: a first set to offset dopant implants in the formation of source and drain extension regions, and a second set to offset dopant implants in the formation of source and drain regions. In accordance with another embodiment of the present invention, the use of inward dielectric spacers for a replacement gate integration scheme eliminates the need for the first set of spacers. Thus, in one embodiment, the width (gate length) of a placeholder gate electrode is not as small as the dimension of the desired final gate electrode because the inward dielectric spacers reduce the width of the trench created upon removing the placeholder gate electrode. In that embodiment, the width of the placeholder gate electrode is approximately equal to the width of the desired final gate electrode plus the width of the offset required for source and drain extension implants, i.e. the width of the first set of spacers that would otherwise be used.

The use of inward dielectric spacers for a replacement gate integration scheme may enable the incorporation of a low-K material adjacent to a gate electrode in a semiconductor device. In accordance with an embodiment of the present invention, the inward dielectric spacers are fabricated after completion of high temperature operations (often greater than 1000 degrees Celsius) normally associated with the fabrication of a semiconductor device, such as a source and drain region anneal process. Inward dielectric spacers composed of thermally-sensitive materials may be included by forming the inward dielectric spacers subsequent to such high temperature operations. In one embodiment, a pair of low-K inward dielectric spacers is formed at a temperature less than approximately 600 degrees Celsius and is only further subjected to temperatures less than approximately the same temperature. Undesirable fringe capacitance in a semiconductor device may be reduced by incorporating such low-K inward dielectric spacers adjacent to the gate electrode in the semiconductor device.

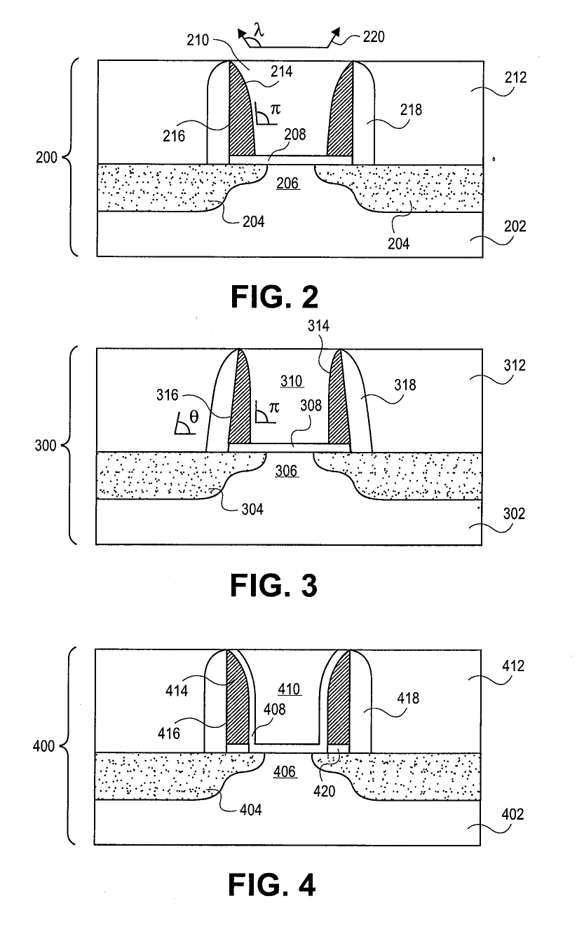

Inward dielectric spacers may be incorporated into a semiconductor device. FIG. 2 illustrates a cross-sectional view representing a semiconductor device having inward dielectric spacers, in accordance with an embodiment of the present invention.

Referring to FIG. 2, a semiconductor device 200 is formed in and above a substrate 202. Source and drain regions 204 define a channel region 206 in substrate 202 and underneath a gate dielectric layer 208. A gate electrode 210 is formed in a dielectric layer 212 and, in particular, in between a pair of inward dielectric spacers 214. Each inward dielectric spacer 214 is formed along a sidewall 216 of a trench in dielectric layer 212. A pair of outward spacers 218 may optionally be disposed between inward dielectric spacers 214 and dielectric layer 212. In such a case, sidewalls 216 of a previously formed trench are created by the surface of outward spacers 218, instead of by the surface of dielectric layer 212.

Sidewalls 216 may have a profile that is an artifact of a previously removed placeholder gate electrode. In one embodiment, sidewalls 216 are substantially vertical, whereas inward dielectric spacers 214 have a tapered profile, as depicted in FIG. 2. The tapered profile of inward dielectric spacers 214 renders each inward dielectric spacer 214 to slope outwards in moving from the bottom of gate electrode 210 to the top of gate electrode 210. Thus, in accordance with an embodiment of the present invention, a substantially vertical profile of a trench formed by removing a placeholder gate electrode is altered to have a tapered profile by incorporating inward dielectric spacers 214. In one embodiment, the angle π of the tapered profile is in the range of 91-120 degrees. In a specific embodiment, the angle π of the tapered profile is in the range of 95-105 degrees.

The top portions of inward dielectric spacers 214 may further be flared, as depicted in FIG. 2. That is, the angle created by the surface of the top portion of each inward dielectric spacer 214 and the top surface of substrate 202 is greater than the angle created by the surface of the bottom portion of each inward dielectric spacer 214 and the top surface of substrate 202. In accordance with an embodiment of the present invention, the top portions of inward dielectric spacers 214 are flared to provide a funnel-shaped profile for the pair of inward dielectric spacers 214, as indicated by the arrows 220. In one embodiment, the angle λ of the flared portion of each inward dielectric spacer 214 is in the range of 95-135 degrees. In a specific embodiment, the angle λ of the flared portion of each inward dielectric spacer 214 is in the range of 105-115 degrees.

Inward dielectric spacers may correct for a re-entrant profile of a trench by creating a tapered profile for the trench. FIG. 3 illustrates a cross-sectional view representing a semiconductor device having inward dielectric spacers adjacent to the sidewalls of a trench having a re-entrant profile, in accordance with an embodiment of the present invention.

Referring to FIG. 3, a semiconductor device 300 is formed in and above a substrate 302. Source and drain regions 304 define a channel region 306 in substrate 302 and underneath a gate dielectric layer 308. A gate electrode 310 is formed in a dielectric layer 312 and, in particular, in between a pair of inward dielectric spacers 314. Each inward dielectric spacer 314 is formed along a sidewall 316 of a trench in dielectric layer 312. A pair of outward spacers 318 may optionally be disposed between inward dielectric spacers 314 and dielectric layer 312. In such a case, sidewalls 316 of a previously formed trench are created by the surface of outward spacers 318, instead of by the surface of dielectric layer 312.

Sidewalls 316 may have a profile that is an artifact of a previously removed placeholder gate electrode. In one embodiment, sidewalls 316 have a re-entrant profile, whereas inward dielectric spacers 314 have a tapered profile, as depicted in FIG. 3. The tapered profile of inward dielectric spacers 314 renders each inward dielectric spacer 314 to slope outwards in moving from the bottom of gate electrode 310 to the top of gate electrode 310. Thus, in accordance with an embodiment of the present invention, a re-entrant profile of a trench formed by removing a placeholder gate electrode is altered to have a tapered profile by incorporating inward dielectric spacers 314. In one embodiment, the angle θ of the re-entrant profile of each sidewall 316 is in the range of 45-89 degrees and the angle π of the tapered profile of each inward dielectric spacer 314 is in the range of 91-120 degrees. In a specific embodiment, the angle θ of the re-entrant profile of each sidewall 316 is in the range of 80-89 degrees and the angle π of the tapered profile of each inward dielectric spacer 314 is in the range of 95-105 degrees. The top portions of inward dielectric spacers 314 may further be flared, as described in association with inward dielectric spacers 214 from FIG. 2.

The gate dielectric layers 208 and 308 described in association with FIGS. 2 and 3, respectively, are disposed between a gate electrode and a substrate. Furthermore, as a consequence of forming inward dielectric spacers subsequent to forming the gate dielectric layers, a portion of the gate dielectric layers may be disposed underneath the inward dielectric spacers, i.e. between a substrate and the inward dielectric spacers, as depicted in FIGS. 2 and 3. However, it may be desirable to form a gate dielectric layer subsequent to forming a pair of inward dielectric spacers. Thus, in one embodiment, a replacement gate dielectric layer is incorporated into a semiconductor device having inward dielectric spacers. FIG. 4 illustrates a cross-sectional view representing a semiconductor device having inward dielectric spacers and a replacement gate dielectric layer, in accordance with an embodiment of the present invention.

Referring to FIG. 4, a semiconductor device 400 is formed in and above a substrate 402. Source and drain regions 404 define a channel region 406 in substrate 402 and underneath a replacement gate dielectric layer 408. A gate electrode 410 is formed in a dielectric layer 412. Gate electrode 410 is in between a portion of gate dielectric layer 410 which is adjacent to the sidewalls of a pair of inward dielectric spacers 414. Each inward dielectric spacer 414 is formed along a sidewall 416 of a trench in dielectric layer 412. A pair of outward spacers 418 may optionally be disposed between inward dielectric spacers 414 and dielectric layer 412. In such a case, sidewalls 416 of a previously formed trench are created by the surface of outward spacers 418, instead of by the surface of dielectric layer 412.

Replacement gate dielectric layer 408 may be formed subsequent to the formation of a pair of inward dielectric spacers. In one embodiment, inward dielectric spacers 414 are first formed above a placeholder gate dielectric layer. The exposed portion of the placeholder gate dielectric layer is then removed and replacement gate dielectric layer 408 is disposed on the surface of substrate 402 and along the sidewalls of inward dielectric layers 414, as depicted in FIG. 4. Thus, in accordance with an embodiment of the present invention, remnants 420 of a placeholder gate dielectric layer are retained between substrate 402 and inward dielectric spacers 414, as is also depicted in FIG. 4. Inward dielectric spacers 414 may have a tapered profile and may further be flared, as described in association with inward dielectric spacers 214 and 314 from FIGS. 2 and 3, respectively.

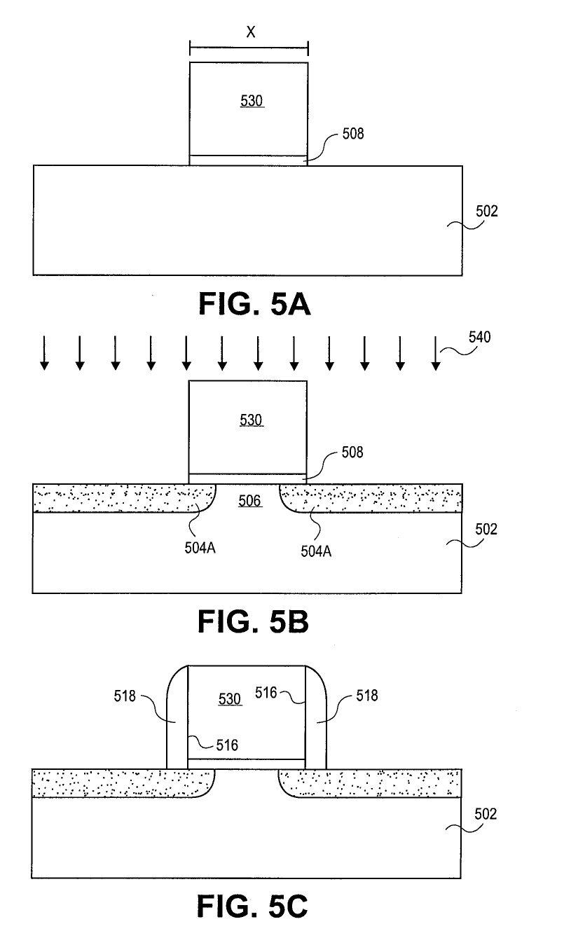

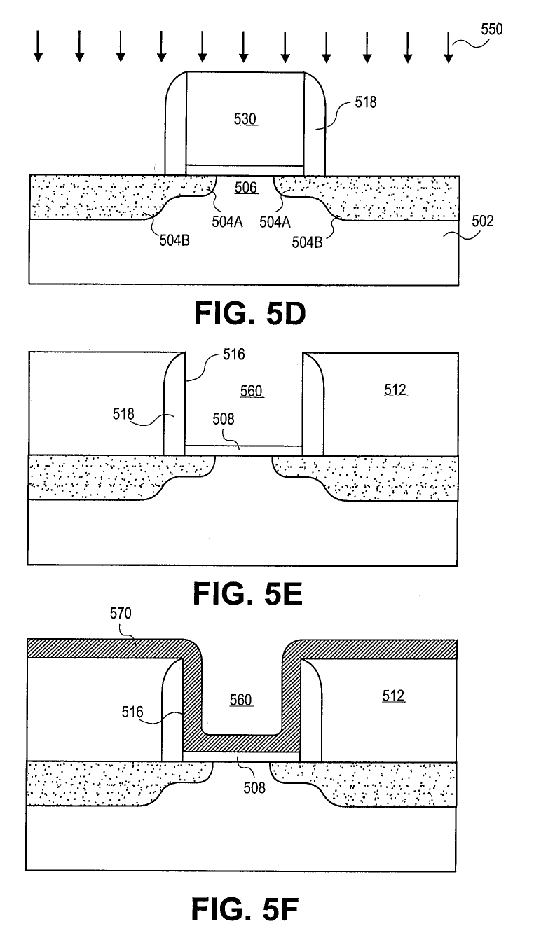

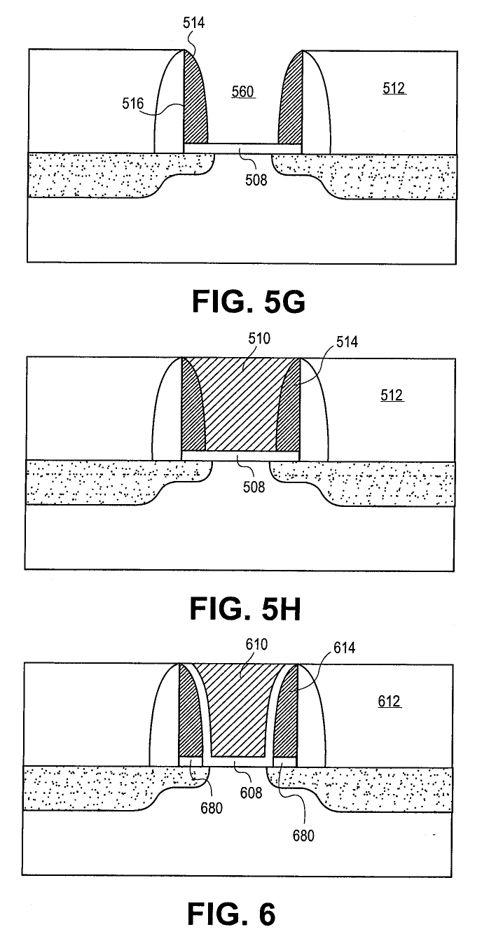

Inward dielectric spacers may be fabricated in a replacement gate integration scheme. FIGS. 5A-5H illustrate cross-sectional views representing operations in a replacement gate integration scheme incorporating inward dielectric spacers, in accordance with an embodiment of the present invention.

Referring to FIG. 5A, a placeholder gate electrode 530 is disposed above a substrate 502. A gate dielectric layer 508 is disposed between gate electrode 530 and substrate 502. In one embodiment, gate dielectric layer 508 is the gate dielectric layer that will ultimately be retained in a fabricated semiconductor device. In another embodiment, gate dielectric layer 508 is a placeholder gate dielectric layer and will ultimately be replaced by a replacement gate dielectric layer.

Substrate 502 may be composed of any material suitable for semiconductor device fabrication. In one embodiment, substrate 502 is a bulk substrate composed of a single crystal of a material which may include, but is not limited to, silicon, germanium, silicon-germanium or a III-V compound semiconductor material. In another embodiment, substrate 502 includes a bulk layer with a top epitaxial layer. In a specific embodiment, the bulk layer is composed of a single crystal of a material which may include, but is not limited to, silicon, germanium, silicon-germanium, a III-V compound semiconductor material and quartz, while the top epitaxial layer is composed of a single crystal layer which may include, but is not limited to, silicon, germanium, silicon-germanium and a III-V compound semiconductor material. In another embodiment, substrate 502 includes a top epitaxial layer on a middle insulator layer which is above a lower bulk layer. The top epitaxial layer is composed of a single crystal layer which may include, but is not limited to, silicon (i.e. to form a silicon-on-insulator (SOI) semiconductor substrate), germanium, silicon-germanium and a III-V compound semiconductor material. The insulator layer is composed of a material which may include, but is not limited to, silicon dioxide, silicon nitride and silicon oxy-nitride. The lower bulk layer is composed of a single crystal which may include, but is not limited to, silicon, germanium, silicon-germanium, a III-V compound semiconductor material and quartz. Substrate 502 may further include dopant impurity atoms.

Placeholder gate electrode 530 may be composed of any material suitable for patterning and for ultimate selective removal in a replacement gate integration scheme. In one embodiment, placeholder gate electrode 530 is composed of a semiconductor material such as, but not limited to, poly-crystalline silicon, doped poly-crystalline silicon, amorphous silicon, doped amorphous silicon or a silicon-germanium alloy. In another embodiment, placeholder gate electrode 530 is composed of an insulating material such as, but not limited to, silicon dioxide, silicon oxy-nitride or silicon nitride.

The use of inward dielectric spacers for a replacement gate integration scheme may ease the constraints of the lithography process used at the placeholder gate electrode patterning step. In accordance with an embodiment of the present invention, inward dielectric spacers will ultimately be used to shrink the width of a trench formed by removing placeholder gate electrode 530. Thus, the critical dimension of placeholder gate electrode 530 need not be as small as the dimension of the desired gate electrode because the inward dielectric spacers may reduce the width of the trench created by removing placeholder gate electrode 530. This reduction in trench width is carried out subsequent to the lithography process used to form placeholder gate electrode 530 and can therefore be used to shrink the critical dimension normally achievable by a particular lithographic process. That is, in an embodiment, placeholder gate electrode 530 is formed by first patterning a photo-resist layer, which is patterned to the smallest dimensions achievable by a particular lithographic process. Then, a trench is formed as a consequence of the removal of placeholder gate electrode 530. The width of the trench is finally reduced to a sub-lithographic dimension by the incorporation of inward dielectric spacers. For example, in one embodiment, placeholder gate electrode 530 has a width “x” of approximately 60 nanometers, while subsequently formed inward dielectric spacers each have a width of approximately 10 nanometers. Thus, in that embodiment, a final width of 40 nanometers is achieved for a gate electrode disposed in a trench formed by removing placeholder gate electrode 530.

Gate dielectric layer 508 may be composed of any material suitable to electrically isolate a gate electrode from substrate 502. In one embodiment, gate dielectric layer 508 is formed by a thermal oxidation process or a chemical vapor deposition process and is composed of a material such as, but not limited to, silicon dioxide or silicon oxy-nitride. In another embodiment, gate dielectric layer 508 is formed by atomic layer deposition and is composed of a high-k dielectric material such as, but not limited to, hafnium oxide, zirconium oxide, hafnium silicate, hafnium oxy-nitride or lanthanum oxide. In an alternative embodiment, gate dielectric layer 508 is a placeholder gate dielectric layer and has a thickness sufficiently thick to act as an etch stop during the subsequent removal of placeholder gate electrode 530, yet sufficiently thin for removal with substantial selectivity to subsequently formed inward dielectric spacers. In a specific alternative embodiment, gate dielectric layer 508 is a placeholder gate dielectric layer composed of silicon dioxide and has a thickness approximately in the range of 2-5 nanometers.

Referring to FIG. 5B, tip extension regions 504A are formed by implanting dopant impurity atoms 540 into substrate 502, as shielded by placeholder gate electrode 530. Tip extension regions 504A define a channel region 506 in substrate 502 underneath gate dielectric layer 508. In accordance with an embodiment of the present invention, placeholder gate electrode 530 has a width greater than the width of a subsequently formed gate electrode and thus tip extension regions 504A may be formed without the use of sidewall spacers adjacent to the sidewalls of placeholder gate electrode 530, as depicted in FIG. 5B. In another embodiment, only very thin sidewall spacers need be used adjacent to the sidewalls of placeholder gate electrode 530 during the formation of tip extension regions 504A.

Tip extension regions 504A may be any regions having opposite conductivity to channel region 506. For example, in accordance with an embodiment of the present invention, tip extension regions 504A are N-type doped regions while channel region 506 is a P-type doped region. In one embodiment, tip extension regions 504A are composed of phosphorous or arsenic dopant impurity atoms with a concentration in the range of 5×10¹⁶-5×10¹⁹ atoms/cm³. In accordance with another embodiment of the present invention, tip extension regions 504A are P-type doped regions while channel region 506 is an N-type doped region. In one embodiment, tip extension regions 504A are composed of boron dopant impurity atoms with a concentration in the range of 5×10¹⁶-5×10¹⁹ atoms/cm³.

Referring to FIG. 5C, a pair of outward dielectric spacers 518 may optionally be formed adjacent to the sidewalls of placeholder gate electrode 530. In accordance with an embodiment of the present invention, the inner sidewalls 516 of outward dielectric spacers 518 will ultimately form the sidewalls of a trench for use in a replacement gate integration scheme. In one embodiment, outward spacers 518 are formed by depositing a dielectric layer over substrate 502 and placeholder gate electrode 530 and subsequently etching the dielectric layer with an anisotropic etch process. In a specific embodiment, outward dielectric spacers 518 are composed of a material which may include, but is not limited to, silicon dioxide, silicon nitride and silicon oxy-nitride.

Referring to FIG. 5D, source and drain regions 504B are formed by implanting dopant impurity atoms 550 into substrate 502, as shielded by placeholder gate electrode 530 and optional outward dielectric spacers 518. Source and drain regions 504B are integrated with tip extension regions 504A to further define channel region 506 in substrate 502. Source and drain regions 504B may be any regions having the same conductivity as tip extension regions 504A. For example, in accordance with an embodiment of the present invention, tip extension regions 504A are N-type doped regions and source and drain regions 504B are also N-type doped regions. In one embodiment, source and drain regions 504B are composed of phosphorous or arsenic dopant impurity atoms with a concentration in the range of 5×10¹⁶-5×10¹⁹ atoms/cm³. In accordance with another embodiment of the present invention, tip extension regions 504A are P-type doped regions and source and drain regions 504B are also P-type doped regions. In one embodiment, source and drain regions 504B are composed of boron dopant impurity atoms with a concentration in the range of 5×10¹⁶-5×10¹⁹ atoms/cm³.

The process used in the formation of source and drain regions 504B may include a high temperature anneal process, e.g. greater than 1000 degrees Celsius, following the dopant impurity atom implantation step. Then, in accordance with an embodiment of the present invention, operations associated with a typical replacement gate integration scheme are carried out. For example, in one embodiment, source and drain regions are metallized in a silicidation process. Subsequently, an inter-layer dielectric layer may be deposited above substrate 502 and placeholder gate electrode 530. In one embodiment, and in accordance with a replacement gate integration scheme, the inter-layer dielectric layer is then planarized to expose the top surface of placeholder gate electrode 530.

Placeholder gate electrode 530 may then be removed by a selective etch process such as a dry etch process or a wet etch process, or a combination thereof. In one embodiment, gate dielectric layer 508 is used as an etch stop layer in an etch process used to remove placeholder gate electrode 530. Referring to FIG. 5E, the removal of placeholder gate electrode 530 leaves a trench 560 disposed in a planarized inter-layer dielectric layer 512. In one embodiment, trench 560 is formed by sidewalls 516 of optional outward dielectric spacers 518, as depicted in FIG. 5E. In an alternative embodiment, trench 560 is formed directly by the sidewalls of inter-layer dielectric layer 512.

Referring to FIG. 5F, a spacer-forming dielectric layer 570 is formed conformal with the top surface of planarized inter-layer dielectric layer 512, with sidewalls 516 of trench 560, and with gate dielectric layer 508. Spacer-forming dielectric layer 570 may be composed of any dielectric material suitable for patterning into inward dielectric spacers with high selectivity to planarized inter-layer dielectric layer 512, to sidewalls 516 of trench 560, and to gate dielectric layer 508. In one embodiment, spacer-forming dielectric layer 570 is composed of a material which may include, but is not limited to, silicon dioxide, silicon nitride and silicon oxy-nitride. Spacer-forming dielectric layer 570 may be deposited by any technique suitable to provide conformal and uniform coverage of trench 560. In one embodiment, spacer-forming dielectric layer 570 is deposited by a technique which may include, but is not limited to, chemical vapor deposition, low-pressure chemical vapor deposition or plasma-enhanced chemical vapor deposition. Spacer-forming dielectric layer 570 may have a thickness approximately equal to the desired width of a subsequently formed inward dielectric spacer. In one embodiment, spacer-forming dielectric layer 570 has a thickness approximately in the range of 50-150 nanometers.

The fabrication of inward dielectric spacers by way of a replacement gate integration scheme may enable the incorporation of a low-K material adjacent to a gate electrode in a semiconductor device. In accordance with an embodiment of the present invention, inward dielectric spacers are fabricated from spacer-forming dielectric layer 570 after completion of all high temperature operations, e.g. the source and drain region anneal process. Thus, in an embodiment, spacer-forming dielectric layer 570 can be composed of a thermally-sensitive material because no further high temperature processing steps are required. In accordance with an embodiment of the present invention, no further process steps are carried out at a temperature above approximately 1000 degrees Celsius. In one embodiment, spacer-forming dielectric layer 570 is composed of a material having a dielectric constant approximately in the range of 2.2-3.5. In a specific embodiment, spacer-forming dielectric layer 570 is composed of a material such as, but not limited to, carbon-doped silicon oxide, boron-doped silicon oxide or boron-doped silicon nitride. In a particular embodiment, spacer-forming dielectric layer 570 is formed at a temperature less than approximately 600 degrees Celsius. In that embodiment, spacer-forming dielectric layer 570 is only further subjected to process steps carried out at temperatures less than approximately 600 degrees Celsius.

Referring to FIG. 5G, spacer-forming dielectric layer 570 is patterned to form a pair of inward dielectric spacers 514 along sidewalls 516 of trench 560. In particular, the portions of spacer-forming dielectric layer 570 above the top surfaces of inter-dielectric layer 512 and above the bottom of trench 560 are removed to expose inter-dielectric layer 512 and gate dielectric layer 508.

Spacer-forming dielectric layer 570 may be patterned to form inward dielectric spacers 514 by any technique suitable to remove the portions of spacer-forming dielectric layer 570 disposed on horizontal surfaces, but that can retain the portions of spacer-forming dielectric layer 570 disposed along sidewalls 516 of trench 560. In accordance with an embodiment of the present invention, spacer-forming dielectric layer 570 is patterned to form inward dielectric spacers 514 by an anisotropic dry etch process. In one embodiment, spacer-forming dielectric layer 570 is composed of silicon dioxide and is patterned to form inward dielectric spacers 514 with a dry etch process using a plasma generated from gases such as, but not limited to, CH₂F₂ and the combination of Cl₂ and HBr. In another embodiment, spacer-forming dielectric layer 570 is composed of silicon nitride and is patterned to form inward dielectric spacers 514 with a dry etch process using a plasma generated from gases such as, but not limited to, CH₂F₂ and CHF₃.

Inward dielectric spacers 514 may have any profile and dimensions suitable to aid in subsequently filling trench 560 with a gate electrode material and suitable to determine the final width of a gate electrode (known in the art as “gate length”). Inward dielectric spacers may have any profile described in association with inward dielectric spacers 214 from FIG. 2. In accordance with an embodiment of the present invention, the broadest width (the width at the surface of gate dielectric layer 508) of each inward dielectric spacer 514 is approximately equal to the thickness of as-deposited spacer-forming dielectric layer 570. In one embodiment, each inward dielectric spacer 514 has a mid-height width (the width half-way between the bottom and the top of each inward dielectric spacer 514) approximately in the range of 5 nanometers-15 nanometers and the resulting partially-filled trench 560 has a bottom width (the width at the exposed surface of gate dielectric layer 508) approximately in the range of 20 nanometers-50 nanometers. Thus, in that embodiment, a gate electrode subsequently formed in trench 560 has a bottom width approximately in the range of 20 nanometers-50 nanometers. In another embodiment, each inward dielectric spacer 514 reduces the starting mid-height width of trench 560 by a factor approximately in the range of 20%-35%. In an embodiment, each inward dielectric spacer 514 has a mid-height width approximately in the range of 10%-30% of the mid-height width of the resulting partially-filled trench 560. Thus, in that embodiment, each inward dielectric spacer 514 has a mid-height width approximately in the range of 10%-30% of the mid-height width of a gate electrode subsequently formed in trench 560.

Referring to FIG. 5H, a gate electrode 510 is disposed in trench 560 between inward dielectric spacers 514 and above gate dielectric layer 508. Gate electrode 510 may be composed of any material suitable for use as an electrode in a semiconductor device. In accordance with an embodiment of the present invention, gate electrode 508 includes a metal. In one embodiment, gate electrode 508 is composed of a material such as, but not limited to a metal nitride, a metal carbide, hafnium, zirconium, titanium, tantalum, aluminum, ruthenium, palladium, platinum, cobalt, nickel, a conductive metal oxide, and a combination thereof. In a specific embodiment, gate electrode 510 is composed of a multi-layer stack including a work-function portion and a trench-fill portion.

The use of inward dielectric spacers 514 in a replacement gate integration scheme may enable the compatibility of ever-smaller trench widths with various gate dielectric material deposition techniques. For example, in accordance with an embodiment of the present invention, the tapered profile on inward dielectric spacer 514 directs deposited material to the bottom of trench 560 being filled with a gate electrode material to form gate electrode 510. This may allow for total and uniform coverage of the bottom of the trench by a deposited material, effectively eliminating the formation of gaps at the corners of filled trench 560 and, hence, at the corners of gate electrode 510. The trench filling process may further be enhanced when the top portion of each inward dielectric spacer 514 is flared. Thus, in one embodiment, the top portion of each inward dielectric spacer 514 is flared to form a funnel shape. The funnel shape may aid with further directing deposited material to the bottom of a trench being filled with the gate electrode material. In one embodiment, gate electrode 510 is formed by depositing a metal-containing layer in the funnel-shaped opening by a physical vapor deposition process.

The semiconductor device formed in FIGS. 5A-5H may be any semiconductor device compatible with a replacement gate integration scheme. For example, in accordance with an embodiment of the present invention, the semiconductor device incorporates a gate electrode, a channel region and a pair of source and drain regions. In one embodiment, the semiconductor device is a device such as, but not limited to, a planar MOS-FET, a memory transistor and a Microelectromechanical System (MEMS). In one embodiment, the semiconductor device is a planar MOS-FET and is an isolated device or is one device in a plurality of nested devices. As will be appreciated for the typical integrated circuit, both N- and P-channel transistors may be fabricated on a single substrate to form a CMOS integrated circuit.

Instead of retaining gate dielectric layer 508, as depicted in FIG. 5G, gate dielectric layer may be a placeholder gate dielectric layer which is removed prior to the formation of gate electrode 510. FIG. 6 illustrates a cross-sectional view representing an operation in a replacement gate integration scheme incorporating inward dielectric spacers and a replacement gate dielectric layer, in accordance with an embodiment of the present invention.

Referring to FIG. 6, a pair of inward dielectric spacers 614 are disposed in a trench formed in an inter-layer dielectric layer 612. A replacement gate dielectric layer 608 is disposed along the sidewalls of inward dielectric spacers 614 and at the bottom of the trench. In an embodiment, replacement gate dielectric layer 608 is formed by atomic layer deposition and is composed of a high-k dielectric material such as, but not limited to, hafnium oxide, zirconium oxide, hafnium silicate, hafnium oxy-nitride or lanthanum oxide. A gate electrode 610 is disposed between the sidewall portions of replacement gate dielectric layer 608 and above the bottom portion of replacement gate dielectric layer 608. In accordance with an embodiment of the present invention, the exposed portion of a placeholder gate dielectric layer is removed prior to the formation of replacement gate dielectric layer 608. In such an embodiment, covered portions of the placeholder gate dielectric layer 680 are retained underneath inward dielectric spacers 614, as depicted in FIG. 6. In a specific embodiment, the corners of inward dielectric spacers 614 are rounded during a wet etch removal of a placeholder gate dielectric layer prior to the formation of replacement gate dielectric layer 608.

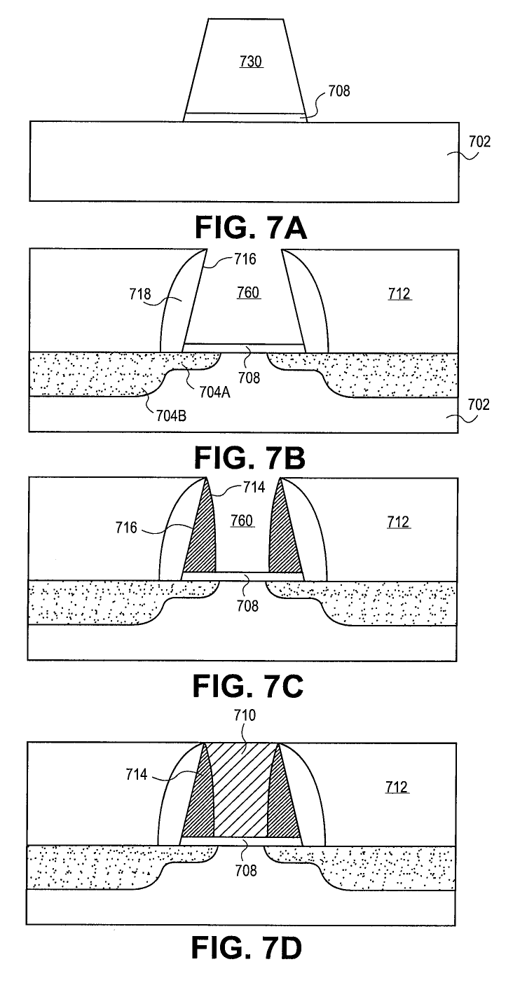

Inward dielectric spacers may correct for a trench having a re-entrant profile by creating a tapered profile for the trench. FIGS. 7A-7D illustrate cross-sectional views representing an operation in a replacement gate integration scheme incorporating inward dielectric spacers adjacent to the sidewalls of a trench having a re-entrant profile, in accordance with an embodiment of the present invention.

Referring to FIG. 7A, a placeholder gate electrode 730 is disposed above a substrate 702. A gate dielectric layer 708 is disposed between gate electrode 730 and substrate 702. In one embodiment, gate dielectric layer 708 is the gate dielectric layer that will ultimately be retained in a fabricated semiconductor device. In another embodiment, gate dielectric layer 708 is a placeholder gate dielectric layer and will ultimately be replaced by a replacement gate dielectric layer. In accordance with an embodiment of the present invention, the sidewalls of placeholder gate electrode 730 have a tapered profile, as depicted in FIG. 7A.

Referring to FIG. 7B, and corresponding with FIG. 5E, the removal of placeholder gate electrode 730 leaves a trench 760 disposed in a planarized inter-layer dielectric layer 712 and above gate dielectric layer 708. Additionally, tip extension regions 704A and source and drain regions 704B have been formed in substrate 702. In one embodiment, trench 760 is formed by sidewalls 716 of optional outward dielectric spacers 718, as depicted in FIG. 7B.

Referring to FIG. 7C, and corresponding with FIG. 5G, a spacer-forming dielectric layer is patterned to form a pair of inward dielectric spacers 714 along sidewalls 716 of trench 760 having a re-entrant profile. In particular, the portions of the spacer-forming dielectric layer above the top surfaces of inter-dielectric layer 712 and above the bottom of trench 760 are removed to expose inter-dielectric layer 712 and gate dielectric layer 708. In accordance with an embodiment of the present invention, inward dielectric spacers 714 correct for a re-entrant profile of trench 760. The dimensions of the re-entrant profile of sidewalls 716 of trench 760 and the tapered profile of inward dielectric spacers 714 may be similar to those for the re-entrant profile of sidewalls 316 and the tapered profile of inward dielectric spacers 314, described in association with FIG. 3. Referring to FIG. 7D, and corresponding with FIG. 5H, a gate electrode 710 is then disposed in trench 760 between inward dielectric spacers 714 and above gate dielectric layer 708.

Thus, inward dielectric spacers for a replacement gate integration scheme have been disclosed. In accordance with an embodiment of the present invention, a semiconductor device is fabricated by first providing a substrate having thereon a placeholder gate electrode disposed in a dielectric layer. The placeholder gate electrode is removed to form a trench in the dielectric layer. A pair of inward dielectric spacers is then formed adjacent to the sidewalls of the trench. Finally, a gate electrode is formed in the trench and adjacent to the pair of inward dielectric spacers. In an embodiment, the top portion of each inward dielectric spacer is flared to form a funnel shape. In one embodiment, the trench in the dielectric layer has a re-entrant profile and each inward dielectric spacer has a tapered profile. In another embodiment, the inward dielectric spacers include a material having a dielectric constant approximately in the range of 2.2-3.5.

What is claimed is:

1. A method for fabricating a semiconductor device, comprising:
providing a substrate having thereon a placeholder gate electrode disposed in a dielectric layer;
removing said placeholder gate electrode to form a trench in said dielectric layer;
forming a pair of dielectric spacers adjacent to the sidewalls of said trench, wherein said trench has a re-entrant profile, and wherein each dielectric spacer of said pair of dielectric spacers has a tapered profile; and
forming a gate electrode in said trench and adjacent to said pair of dielectric spacers.

2. The method of claim 1, wherein the top portion of each dielectric spacer of said pair of dielectric spacers is flared to form a funnel-shaped opening in said trench.

3. The method of claim 2, wherein forming said gate electrode comprises depositing a metal-containing layer in said funnel-shaped opening by a physical vapor deposition process.

4. The method of claim 1, wherein said pair of dielectric spacers comprises a material having a dielectric constant approximately in the range of 2.2-3.5.

5. The method of claim 4, wherein said pair of dielectric spacers is formed at a temperature less than approximately 600 degrees Celsius.

6. The method of claim 4, wherein said pair of dielectric spacers comprises a material selected from the group consisting of carbon-doped silicon oxide, boron-doped silicon oxide and boron-doped silicon nitride.

7. The method of claim 1, wherein each dielectric spacer of said pair of dielectric spacers has a mid-height width approximately in the range of 5 nanometers-15 nanometers, and wherein said gate electrode has a bottom width approximately in the range of 20 nanometers-50 nanometers.

8. The method of claim 1, wherein said pair of dielectric spacers reduces the mid-height width of said trench by a factor approximately in the range of 20%-35%.

9. A semiconductor device, comprising:
a substrate having thereon a gate electrode disposed in a dielectric layer;
a pair of source and drain regions in said substrate on either side of said gate electrode; and
a pair of dielectric spacers adjacent to the sidewalls of said gate electrode, wherein each dielectric spacer is between said gate electrode and said dielectric layer, wherein the top portion of each dielectric spacer of said pair of dielectric spacers is flared to form a funnel shape, wherein the portions of said dielectric layer adjacent to said pair of dielectric spacers have a re-entrant profile, and wherein each dielectric spacer of said pair of dielectric spacers has a tapered profile.

10. The semiconductor device of claim 9, wherein said pair of dielectric spacers comprises a material having a dielectric constant approximately in the range of 2.2-3.5.

11. The semiconductor device of claim 10, wherein said pair of dielectric spacers comprises a material selected from the group consisting of carbon-doped silicon oxide, boron-doped silicon oxide and boron-doped silicon nitride.

12. The semiconductor device of claim 9, wherein each spacer of said pair of dielectric spacers has a mid-height width approximately in the range of 10%-30% of the mid-height width of said gate electrode.

13. The semiconductor device of claim 9, further comprising:
a gate dielectric layer disposed between said substrate and said gate electrode, wherein a portion of said gate dielectric layer is underneath said pair of dielectric spacers.

14. The semiconductor device of claim 9, further comprising:
a gate dielectric layer disposed between said substrate and said gate electrode, wherein a portion of said gate dielectric layer is adjacent to the sidewalls of said pair of dielectric spacers.

15. A semiconductor device, comprising:
a substrate having thereon a gate electrode disposed in a dielectric layer;
a pair of source and drain regions in said substrate on either side of said gate electrode; and
a pair of dielectric spacers adjacent to the sidewalls of said gate electrode, wherein each dielectric spacer is between said gate electrode and said dielectric layer, and wherein said pair of dielectric spacers comprises a material having a dielectric constant approximately in the range of 2.2-3.5.

16. The semiconductor device of claim 15, wherein the portions of said dielectric layer adjacent to said pair of dielectric spacers have a re-entrant profile, and wherein each dielectric spacer of said pair of dielectric spacers has a tapered profile.

17. The semiconductor device of claim 15, wherein each spacer of said pair of dielectric spacers has a mid-height width approximately in the range of 10%-30% of the mid-height width of said gate electrode.

18. The semiconductor device of claim 15, wherein said pair of dielectric spacers comprises a material selected from the group consisting of carbon-doped silicon oxide, boron-doped silicon oxide and boron-doped silicon nitride.

19. The semiconductor device of claim 15, further comprising:
a gate dielectric layer disposed between said substrate and said gate electrode, wherein a portion of said gate dielectric layer is underneath said pair of dielectric spacers.

20. The semiconductor device of claim 15, further comprising:
a gate dielectric layer disposed between said substrate and said gate electrode, wherein a portion of said gate dielectric layer is adjacent to the sidewalls of said pair of dielectric spacers.
